(19) United States
(12) Patent Application Publication
(10) Pub. No.: US 2015/0047702 A1
(43) Pub. Date: Feb. 19, 2015

(54) Method of design and growth of single-crystal 3D nanostructured solar cell or detector

(71) Applicant: The Board of Trustees of the Leland Stanford Junior University, Palo Alto, CA (US)

(72) Inventors: Anjia Gu, Menlo Park, CA (US); Yijie Huo, Cupertino, CA (US); Dong Liang, Fremont, CA (US); Yangsen Kang, Stanford, CA (US); James S. Harris, JR., Stanford, CA (US)

(21) Appl. No.: 14/531,492

(22) Filed: Nov. 3, 2014

Related U.S. Application Data
(63) Continuation of application No. 13/470,195, filed on May 11, 2012, now abandoned.
(60) Provisional application No. 61/518,830, filed on May 12, 2011.

(51) Int. Cl. H01L 31/0236; H01L 31/0352

(52) U.S. Cl. CPC H01L 31/02366; H01L 31/035281
USPC 136/256

(57) ABSTRACT

Photovoltaic devices conformally deposited on a nano-structured substrate having hills and valleys have corresponding hills and valleys in the device layers. We have found that disposing an insulator in the valleys of the device layers such that the top electrode of the device is insulated from the device layer valleys provides beneficial results. In particular, this insulator prevents electrical shorts that otherwise tend to occur in such devices.

### CROSS REFERENCE TO RELATED APPLICATIONS

This application is a continuation of U.S. Pat. No. 13/470,195, filed on May 11, 2012 and hereby incorporated by reference in its entirety.

Application Ser. No. 13/470,195 claims the benefit of U.S. provisional patent application 61/518,830, filed on May 12, 2011, entitled “Method of design and growth of single-crystal 3D nanostructured solar cell or detector”, and hereby incorporated by reference in its entirety.

### FIELD OF THE INVENTION

This invention relates to photovoltaic devices on a nano-structured substrate.

### BACKGROUND

Photovoltaic devices are of considerable interest for various applications (solar cells, detectors, etc.). Numerous methods have been considered to provide improved performance and reduced cost, especially for solar cell applications. One approach that has been considered in the art (e.g., in US 2010/0240167) is conformal deposition of solar cell layers on nano-structured substrates. In this work, atomic layer deposition (ALD) is used to provide the conformal deposition, and the advantages as described for this approach include increased efficiency of charge extraction, and increased optical absorption for thin solar cell layers because of the 3-D architecture provided by the nano-structured substrate. However, it can be difficult in practice to actually fabricate working devices according to these principles, and it would be an advance in the art to provide improved device structures and/or growth methods.

### SUMMARY

When device layers are conformally grown on a substrate having nano-scale hills and valleys, the result is corresponding hills and valleys in the device layers. We have found that planar crystal defects (e.g., grain boundaries, anti-phase domains, etc.) tend to form in the valley parts of the device layers. One way this can occur is when device layer growth proceeds mainly from the sides of the substrate hills. In this case, planar defects can form where device layer material grows from adjacent hill sides and merges. Such merging occurs in the valleys, but not on the hills.

The most significant adverse effect of such defects is that they can provide a direct electrical short to the device. For example, a solar cell having a metallic top electrode disposed on the device layers can effectively be shorted between the top electrode and the substrate by such planar defects, which would completely ruin device performance.

We have found, surprisingly, that this problem of electrical shorting can be effectively solved by disposing an electrical insulator in the valleys formed by the device layers after device layer deposition is complete (i.e., just before depositing the top electrode). This prevents a direct electrical short between the metallic top electrode and the substrate because the defects are in the valleys, where the insulator separates the top electrode from the defects. Although the planar defects will still lead to some excess loss (e.g., locally enhanced recombination, parasitic current conduction etc.), these effects have a much less severe impact on device performance than the kind of direct electrical short that is prevented by the present approach. Accordingly, device performance can be significantly improved by insulating the valleys in a hill and valley nano-structured device. Surprisingly, this improvement can be obtained without removing the underlying planar defects.

This approach provides numerous advantages. These advantages include: 1) reduced reflectance; 2) increased optical angle of acceptance; 3) compatibility with growth on various substrates, such as flexible and/or inexpensive substrates; and 4) capability of providing high-efficiency multi-junction solar cells with reduced manufacturing and/or installation cost.

The present approach has numerous applications. Any and all photovoltaic device applications can benefit from this approach. Specific applications and/or locations include solar utilities and solar farms; building roofs; window glass; curtains; wearable devices such as helmets, back packs, etc.; automobiles; emergency chargers; power supplies for field applications; satellites; space stations; remote controlled robotic rollover (e.g., as in a planetary exploration mission); solar cars; etc.

### BRIEF DESCRIPTION OF THE DRAWINGS

FIG. 1 shows an embodiment of the invention.

FIGS. 2a-h show an exemplary fabrication sequence for embodiments of the invention.

FIG. 3 is an SEM image demonstrating conformal deposition on a nano-structured substrate using metal-organic chemical vapor deposition (MOCVD).

FIG. 4 shows calculated reflectance spectra for nano-wires and nano-pyramids compared to a planar surface.

FIG. 5 shows absorption vs. incident angle for various device structures.

FIG. 6a shows an experimental device structure according to an embodiment of the invention.

FIG. 6b shows a corresponding planar control structure.

FIGS. 7a-b show results for the structures of FIGS. 6a-b.

FIGS. 8a-b show an alternate embodiment of the invention.

FIGS. 9a-b show some examples of suitable nano-scale substrate protrusions for use with embodiments of the invention.

### DETAILED DESCRIPTION

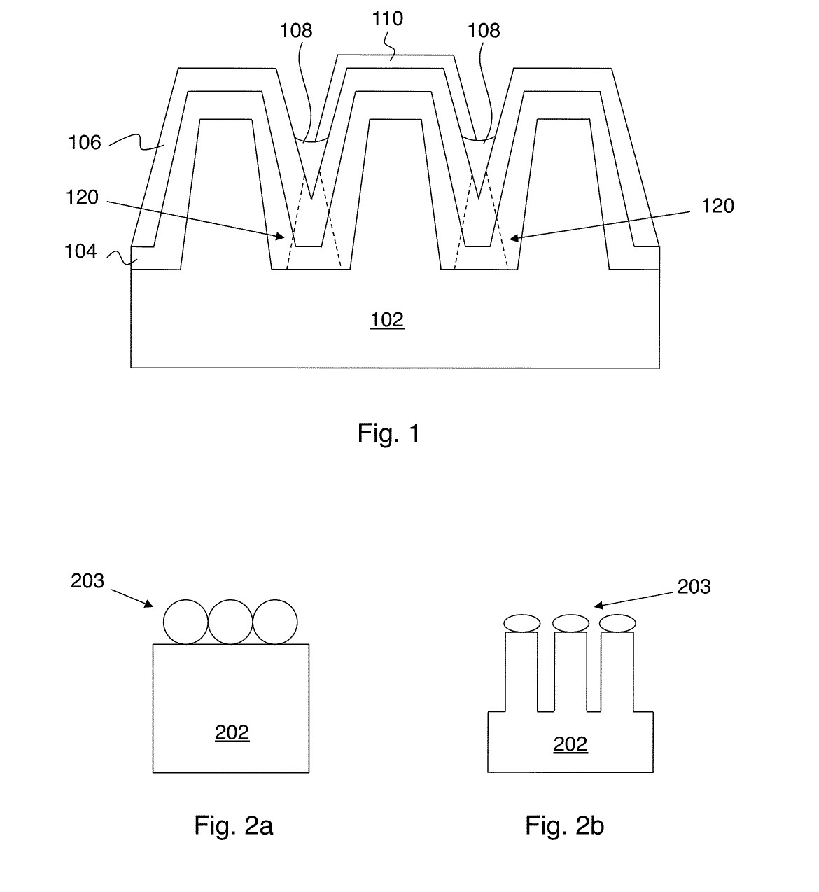

FIG. 1 shows an exemplary embodiment of the invention. In this example, a nano-structured substrate 102 has nano-scale protrusions that create nano-scale hills and nano-scale valleys as shown. As used herein, nano-scale refers to dimensions in sub-wavelength region, preferably between 300 to 900 nm. A multi-layer semiconductor structure is conformally deposited on substrate 102. In this example, the semiconductor multi-layer structure includes layers 104 and 106, which could be, for example, p-type and n-type layers of a PN junction solar cell. The semiconductor multi-layer structure includes nano-scale device hills and device valleys that correspond to the hills and valleys of the substrate, because the semiconductor multi-layer structure is conformally deposited. An electrical insulator 108 is disposed in the device valleys, e.g., as shown on FIG. 1. A top electrode 110 is disposed on the multi-layer semiconductor structure and electrical insulator 108 such that top electrode 110 makes contact with a top layer of the multi-layer structure (e.g., layer 106) only where the top layer is not covered by electrical insulator 108.

As indicated above, the purpose of insulator 108 is to prevent planar defects in the valleys of the device layers from shorting the device out. Such defects are schematically shown on FIG. 1 with dotted lines and are collectively referenced as 120. Formation of defects 120 is attributed to merging of independent regions during growth (e.g., growth from two facing side surfaces of a valley will merge in the middle). Such merging has been found to occur in the valleys of the device layers, but not in the hills of the device layers.

Practice of the invention does not critically depend on the composition of substrate 102. Semiconductor substrates such as Si, GaAs, etc. can be employed. Low cost and/or flexible substrates can also be employed. This provides the ability to bond low-cost, high-performance solar cells to wearable materials (e.g., clothing). The flexible substrate can be metal (Al, Cu) foil, polymer, plastic or any wearable material. Preferably, substrate 102 is lattice matched to the semiconductor multi-layer structure.

Practice of the invention also does not critically depend on the composition of the semiconductor multi-layer structure. The active materials in the semiconductor multi-layer structure can be any suitable semiconductors such as GaAs, AlGaAs, InGaP, InGaAs, GaInAsNSb, Ge, Si, etc. Several exemplary multi-layer structures are included in the following description. The composition of insulator 108 is not critical for practicing the invention. Any insulator that is compatible with processing the other parts of the device structure can be employed. The composition of electrode 110 is also not critical for practicing the invention. Often, it is preferred for electrode 110 to be configured as a metallic finger electrode that covers a small faction of the device area while providing high current collection efficiency.

Transparent materials can also be employed in electrode 110. These principles are applicable to any kind of photovoltaic device, such as solar cells, photodetectors, etc.

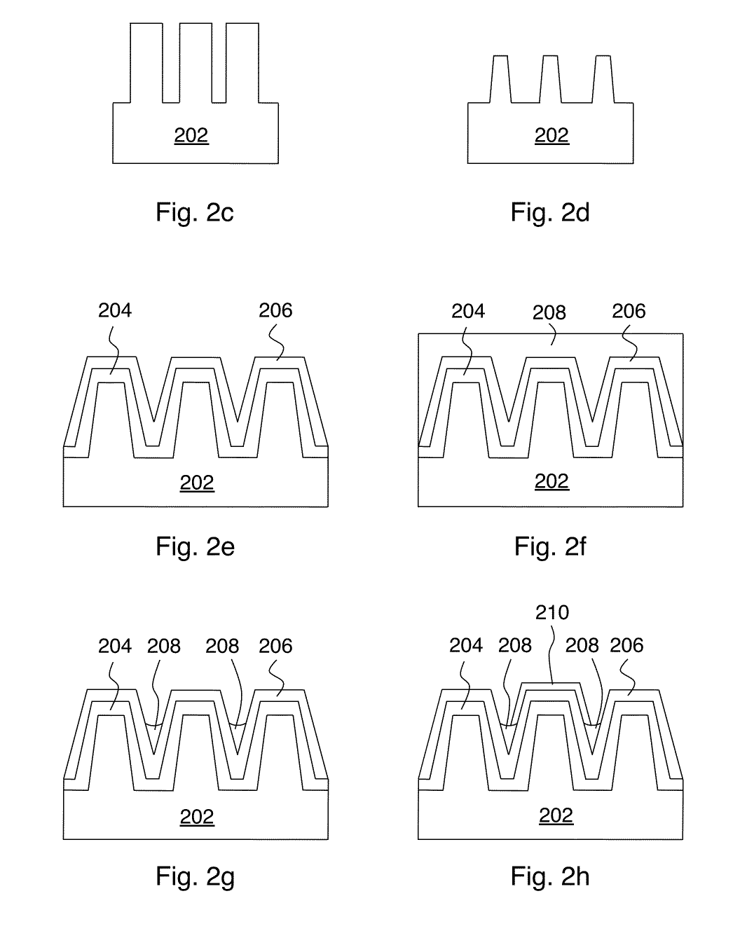

FIGS. 2a-h show an exemplary fabrication sequence for embodiments of the invention. In this example, we start with silica nanospheres 203 disposed on a n-type GaAs substrate 202, as shown on FIG. 2a. Reactive ion etching (RIE) leads to a structure shown on FIG. 2b, where etching between the nano-spheres has created nano-pillars. FIG. 2c shows the result of removing the silica nano-spheres, which can be done with a suitable etch (e.g., dilute hydrofluoric acid). FIG. 2d shows the result of wet chemical etching. This step removes material that may have defects in it as a result of the previous RIE step, and can also be used to control the shape of the nano-scale protrusions. The result of this step is a nano-structured GaAs substrate 202 (analogous to 102 on FIG. 1). Any suitable etchant(s) can be employed here. Further details relating to this preferred approach for providing the nano-structured substrate can be found in US 2011/0121431, which is hereby incorporated by reference in its entirety. Any other method of providing a nano-structured substrate can also be employed.

FIG. 2e shows the result of conformal deposition of layers 204 (n-type GaAs) and 206 (p-type GaAs) on substrate 202. Any conformal deposition technique can be employed, such as atomic layer deposition (ALD), molecular beam epitaxy (MBE) and metal-organic chemical vapor deposition (MOCVD). For MOCVD growth, we have found that growth at low temperature is conformal, but tends to have poor crystal quality. MOCVD growth at high temperature has good crystal quality, but tends not to be conformal. To overcome this problem, we have developed a two step MOCVD process that provides both conformal deposition and good crystal quality. More specifically, the first step is to grow a thin seed layer with thickness between 20 to 50 nm at low temperature (e.g. 500-550 C) to provide uniform nucleation on 3-D surfaces. All the other layers are then deposited at higher temperature (e.g. 650-700 C) to enable atomic surface migration to form high quality single-crystal material. Using this two-step method, single crystal III-V p-n junctions can be grown conformally forming core-shell single crystal nanostructures. The shape of the nanostructures tends to automatically evolve into nanopyramid-like structures after growth. Thus, this two step growth method is an important difference from conventional approaches for nanostructuredsolar cells, because it enables high quality single-crystal growth of active absorbing layers of the 3D nanostructured solar cell.

FIG. 2f shows the results of depositing insulator 208 on the structure. In this example, PMMA (poly(methyl methacrylate)) is employed as the insulator. FIG. 2g shows the result of partially removing insulator 208, which can be done with a timed UV-ozone treatment. Insulator 208 will remain in the device valleys (as shown), because the insulator thickness is greatest at these locations. FIG. 2h shows the result of depositing an electrode 210 on the top of the structure. As a result of the presence of insulator 208, electrode 210 is insulated from the device valleys.

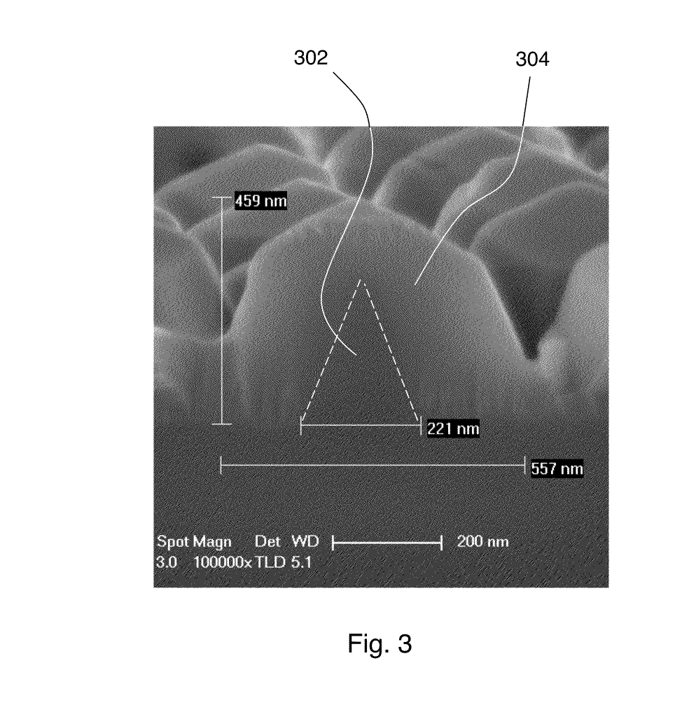

FIG. 3 is an SEM image demonstrating conformal deposition on a nano-structured substrate using MOCVD. Here, 302 is a Ge nanopyramid, and 304 is a conformally deposited GaAs shell having good crystal quality.

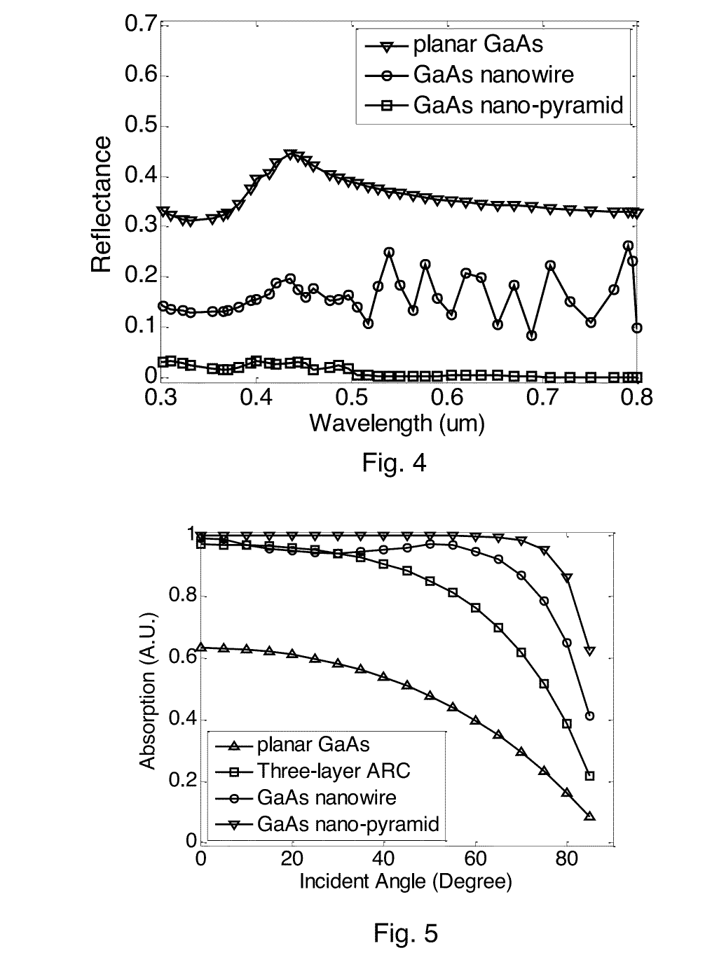

One of the main advantages of using a nano-structured substrate for solar cell applications is reduced reflectance. Conventionally, solar cell reflectance can be reduced using an anti-reflection coating, but such a coating increases cost and may only reduce reflectance over a limited range of incidence angles. FIG. 4 shows calculated (using rigorous coupled wave analysis (RCWA)) reflectance spectra for nano-wires and nano-pyramids compared to a planar surface. Here it is apparent that the reflectance of a planar GaAs surface is very large, and that nano-pyramids provide low reflectance.

FIG. 5 shows calculated absorption vs. incident angle for various device structures at 550 nm. This is another way of considering the effect of reflectance on device performance. Here it is apparent that nanostructured devices (e.g., nanowires, nano-pyramids) provide low reflection over a broader angular range than a 3-layer anti-reflection coating (ARC). Having a large optical angle of acceptance is very helpful in practice, since it can enable the elimination of solar tracking from system design, thereby greatly reducing complexity and cost.

According to a calculation for a realistic application, a nano-pyramid solar cell provided around 20% more energy than a comparable planar control cell over a 24 hour period, mainly due to the increased angle of acceptance. In this calculation, it was assumed that no solar tracking was performed, and that the planar cell had a 3-layer ARC.

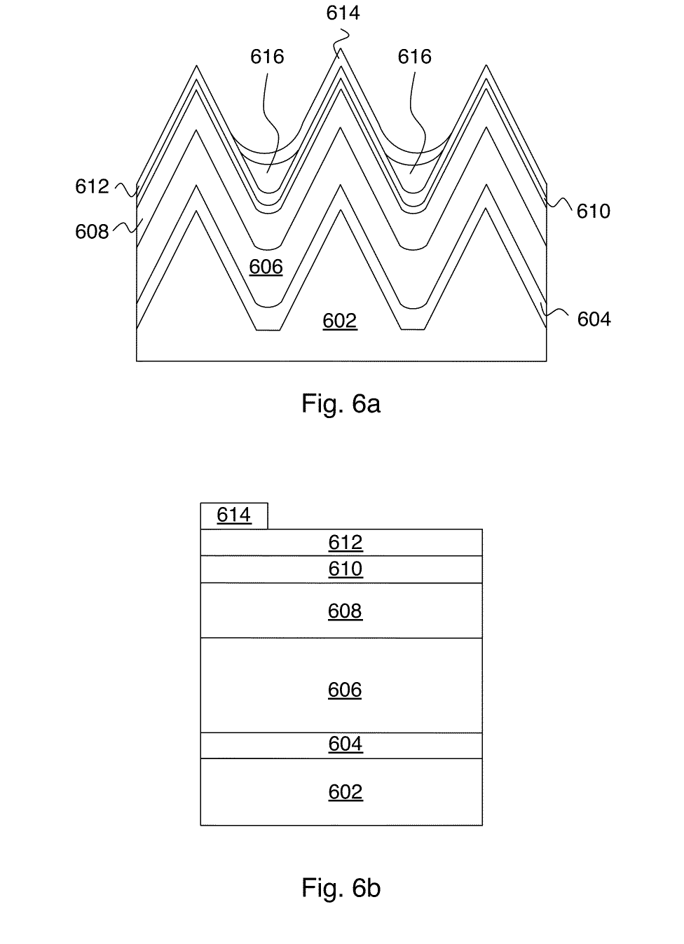

Devices according to the above-described principles have been fabricated and tested. FIG. 6a shows an experimental device structure according to an embodiment of the invention. FIG. 6b shows a corresponding planar control structure. Here 602 is an n-type GaAs substrate, 604 is an n++ GaAs contact layer (thickness 10 nm, doping 1e19 cm⁻³), 606 is n− GaAs (thickness 140 nm, doping 5e17 cm⁻³), 608 is p+ GaAs (thickness 60 nm, doping 3e18 cm⁻³), 610 is p++ Al_{0.85}Ga_{0.15}As window layer (thickness 10 nm, doping 1e19 cm⁻³) to reduce the recombination of minority carrier at the surface, and 612 is a p++ GaAs contact layer (thickness 10 nm, doping 1e19 cm⁻³). The top electrode is referenced as 614, and a PMMA insulator is referenced as 616.

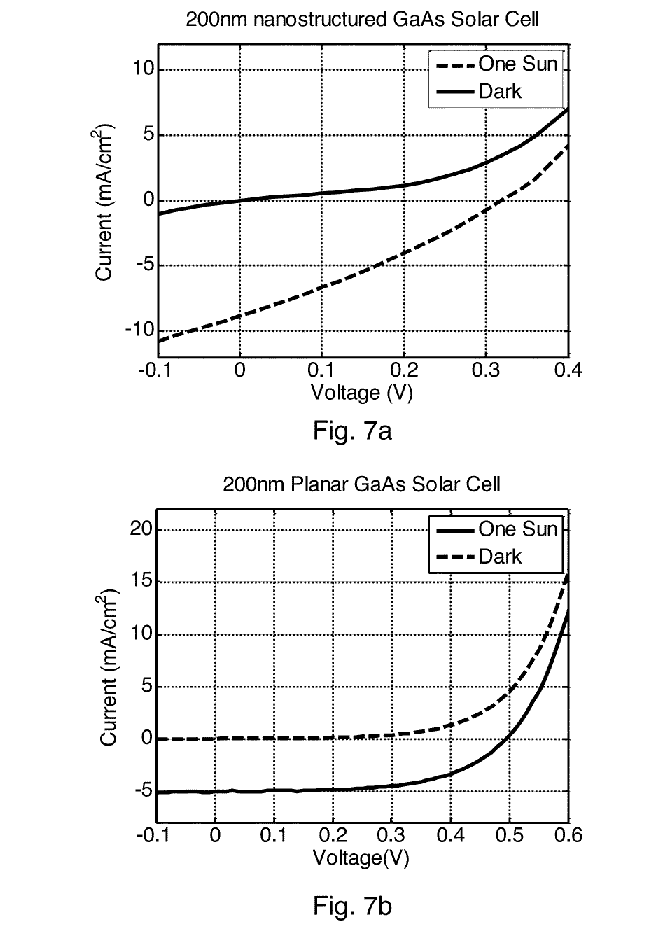

FIGS. 7a-b show results for the structures of FIGS. 6a-b. More specifically, FIG. 7a shows measured I-V curves for the nano-structured device of FIG. 6a, and FIG. 7b shows measured I-V curves for the planar control device of FIG. 6b. Numerical results are tabulated below.

| | Control (planar) | Nano-structured |
|---|---|---|
| J_{sc} (mA/cm2) | 5.104 | 9.25 |
| Fill factor (%) | 57.468 | 28.155 |
| V_{oc} (V) | 0.49 | 0.32 |
| Efficiency (%) | 1.4371 | 0.8 |

These results demonstrate a working nano-structured device. If the top electrode of a nano-structured device is shorted to the substrate by defects, the efficiency would be much lower. Note that the short circuit current (J_{sc}) is increased by 80% in the nano-structured device as compared to the planar control sample, although the nano-structured device also has somewhat lower fill factor, V_{oc} and efficiency.

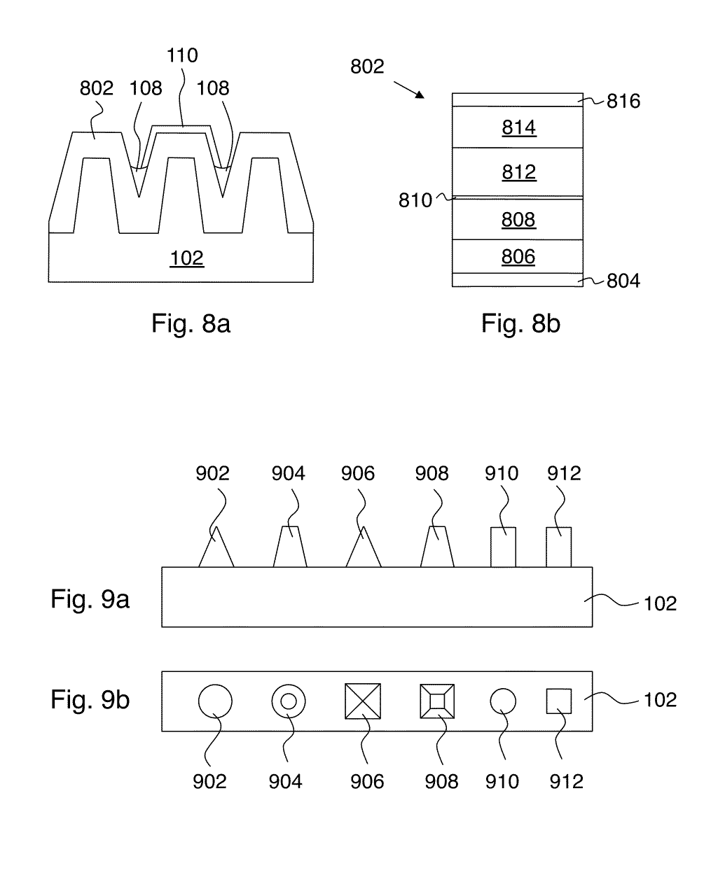

Practice of the invention does not depend critically on the number or nature of the layers included in the semiconductor multi-layer structure. Any semiconductor multi-layer structure can be included in devices according to the present principles. FIGS. 8a-b show an exemplary alternate embodiment of the invention (2 junction solar cell). Here substrate 102, insulator 108 and top electrode 110 are as described above. Multi-layer structure 802 is conformally deposited on substrate 102. FIG. 8b shows multi-layer semiconductor structure 802 in detail. In this example, substrate 102 is Silicon, and layer 804 is a Ge inter-layer that provides a lattice match of Si to GaAs. The first junction is formed by n-type GaAs layer 806 and p-type GaAs layer 808. The second junction is formed by n-type AlGaAs layer 812 and p-type AlGaAs layer 814. The two junctions are electrically coupled to each other by a tunnel junction region 810 (which includes heavily doped n-type and p-type sub-layers, not shown). A p++ top contact layer 816 is disposed on top of the second junction. Here, the device is preferably illuminated from the top side of the figure, so that the AlGaAs junction (which has higher band gap) is encountered first by the incoming solar radiation. However, practice of the invention does not depend critically on whether the illumination is from the top (i.e., toward the substrate through the active layers) or the bottom (i.e., through the substrate toward the active layers), and there are also other embodiments where illumination from the bottom is preferred.

Practice of the invention also does not depend critically on the shape of the substrate protrusions. These principles are applicable in any situation where conformal growth over features having hills and valleys is performed. FIGS. 9a-b show some examples of suitable nano-scale substrate protrusions for use with embodiments of the invention. Here FIG. 9a is a side view and FIG. 9b is a corresponding top view. Suitable protrusion shapes include, but are not limited to: nano-pillars (910, 912), nano-pyramids (906), nano-cones (902), truncated nano-pyramids (908), and truncated nano-cones (904). Nano-pillars, nano-pyramids and truncated nano-pyramids can have any number of lateral sides. In the examples of FIGS. 9a-b, 4-sided pyramids and pillars are shown. Such 4-sided shapes can be square or rectangular. Pillars or truncated pyramids can have a faceted top rather than a flat top.

1. A photovoltaic device comprising:
a nano-structured semiconductor substrate having a plurality of nano-scale protrusions disposed to create nano-scale substrate hills and nano-scale substrate valleys;
a multi-layer semiconductor structure conformally deposited on the substrate, whereby the multi-layer semiconductor structure has nano-scale device hills and nano-scale device valleys that correspond to the substrate hills and substrate valleys;
an electrical insulator disposed in the device valleys; and
a top electrode disposed on the multi-layer semiconductor structure and electrical insulator such that the top electrode makes contact with a top layer of the multi-layer structure only where the top layer is not covered by the electrical insulator;
wherein the multi-layer semiconductor structure has defects beneath the electrical insulator that are formed by merging of independent regions during growth, and wherein the electrical insulator disposed in the device valleys prevents electrical shorting of the photovoltaic device by the defects.

2. The photovoltaic device of claim 1, wherein the multi-layer semiconductor structure comprises a single-junction solar cell structure.

3. The photovoltaic device of claim 1, wherein the nano-scale protrusions comprise nano-cones.

4. The photovoltaic device of claim 1, wherein the substrate is lattice matched to the multi-layer semiconductor structure.

5. The photovoltaic device of claim 4, wherein the multi-layer semiconductor structure includes a lattice matching interlayer, wherein the lattice matching interlayer is lattice matched to the substrate.
